(19) United States
(12) Patent Application Publication
(10) Pub. No.: US 2019/0096770 A1
(43) Pub. Date: Mar. 28, 2019

(54) SEMICONDUCTOR DEVICES

(71) Applicant: Samsung Electronics Co., Ltd., Suwon-si (KR)

(72) Inventors: HYUNG-SEOK HONG, Ansan-si (KR); SUK HOON KIM, Hwaseong-si (KR); IN HEE LEE, Suwon-si (KR); HYE-LAN LEE, Hwaseong-si (KR)

(21) Appl. No.: 15/955,771

(22) Filed: Apr. 18, 2018

(30) Foreign Application Priority Data
Sep. 25, 2017 (KR) 10-2017-0123312

(51) Int. Cl. H01L 21/8238; H01L 27/092; H01L 27/108; H01L 29/51; H01L 29/49; H01L 21/8234; H01L 21/762; H01L 21/8239

(52) U.S. Cl. CPC H01L 21/823857; H01L 27/092; H01L 27/108; H01L 29/517; H01L 21/8239; H01L 21/823462; H01L 21/823807; H01L 21/76224; H01L 29/4966

(57) ABSTRACT

Semiconductor device as provided may include a substrate with an NMOS region and a PMOS region, and a first transistor in the NMOS region that includes a first gate stack and a first source/drain region on at least one side of the first gate stack. The semiconductor device may further include a second transistor in the PMOS region that includes a second gate stack and a second source/drain region on at least one side of the second gate stack. The first gate stack may include a first insulating film, a first gate electrode layer of first thickness, additional gate electrode layers, a and a first silicon layer, which may be sequentially laminated. The second gate stack may include a second insulating film, a fourth gate electrode layer of second thickness greater than the first thickness, additional gate electrode layers, and a second silicon layer, which may be sequentially laminated.

The present application claims priority under 35 U.S.C. § 119 to Korean Patent Application No. 10-2017-0123312, filed on Sep. 25, 2017 in the Korean Intellectual Property Office, the disclosure of which is herein incorporated by reference in its entirety for all purposes.

### BACKGROUND

### 1. Technical Field

The present disclosure relates to semiconductor devices.

### 2. Description of the Related Art

A semiconductor memory element such as a dynamic random access memory (DRAM) may include a cell array region and a peripheral region or a core-peri region. In particular, the peripheral region or the core-peri region may include a region in which a PMOS transistor is formed, and a region in which an NMOS transistor is formed. Recently, gate structures having different structures have been disposed in the region in which the PMOS transistor is formed and the region in which the NMOS transistor is formed.

### SUMMARY

Aspects of the present disclosure provide methods for manufacturing semiconductor devices having improved operating characteristics.

However, aspects of the present disclosure are not limited to those set forth herein. The above and other aspects of the present disclosure will become more apparent to those of ordinary skill in the art to which the present disclosure pertains through reference to the detailed description of various example embodiments of the present inventive concepts given herein.

According to some aspects of the present disclosure, a semiconductor device may be provided. The semiconductor device may comprise a substrate including an NMOS region and a PMOS region, a first transistor in the NMOS region and a second transistor in the PMOS region. The first transistor may include a first gate stack and a first source/drain region on at least one side of the first gate stack. The second transistor may include a second gate stack and a second source/drain region on at least one side of the second gate stack. The first gate stack may include a first high-dielectric constant insulating film, a first gate electrode layer having a first thickness, a second gate electrode layer, a third gate electrode layer, and a first silicon layer which may be sequentially laminated. The second gate stack may include a second high-dielectric constant insulating film, a fourth gate electrode layer having a second thickness greater than the first thickness, a fifth gate electrode layer, a sixth gate electrode layer, and a second silicon layer which may be sequentially laminated. The second gate electrode layer and the fifth gate electrode layer may include a lanthanum-based material.

According to some aspects of the present disclosure, a semiconductor device is provided. The semiconductor device may comprise a substrate which includes a cell array region including a buried gate structure, and a peripheral region including a NMOS region and a PMOS region having different conductivity types, a first transistor in the NMOS region, and a second transistor in the PMOS region. The first transistor may include a first gate stack, a first source/drain region on at least one side of the first gate stack, and a first channel region below the first gate stack. The second transistor may include a second gate stack, a second source/drain region on at least one side of the second gate stack, and a second channel region below the second gate stack. The first gate stack may include a first high-dielectric constant insulating film, a first gate electrode layer having a first thickness, a second gate electrode layer, a third gate electrode layer, and a first silicon layer which may be sequentially laminated. The second gate stack may include a second high-dielectric constant insulating film, a fourth gate electrode layer having a second thickness greater than the first thickness, a fifth gate electrode layer, a sixth gate electrode layer, and a second silicon layer which may be sequentially laminated. The first channel region and the second channel region may include materials different from each other, and the second gate electrode layer and the fifth gate electrode layer may include a lanthanum element.

According to some aspects of the present disclosure, a semiconductor device may be provided. The semiconductor device may comprise a substrate including an NMOS region and a PMOS region, a first gate stack on the substrate in the NMOS region, a first channel region below the first gate stack, a second gate stack on the substrate in the PMOS region and a second channel region which may be below the second gate stack and which may include a material different from the first channel region. The first gate stack may include a first high-dielectric constant insulating film, a first gate electrode layer, a second gate electrode layer, a third gate electrode layer, and a first silicon layer which may be sequentially laminated. The second gate stack may include a second high-dielectric constant insulating film, a fourth gate electrode layer, a fifth gate electrode layer, a sixth gate electrode layer, and a second silicon layer which may be sequentially laminated. The second channel region may include a germanium element. The first gate electrode layer and the fourth gate electrode layer may include the same metal element. The second gate electrode layer may include a lanthanum element, and the fifth gate electrode layer may include any one of a lanthanum element and an aluminum element.

### BRIEF DESCRIPTION OF THE DRAWINGS

The above and other aspects and features of the inventive concepts provided herein will become more apparent by describing in detail example embodiments thereof with reference to the attached drawings, in which:

FIGS. 1 through 4 are cross-sectional views for explaining a semiconductor device according to some embodiments of the present disclosure, respectively;

FIG. 5 is a plan view of a substrate of a semiconductor device according to some embodiments of the present disclosure;

FIG. 6 is an enlarged view of a first region R1 of FIG. 5;

FIGS. 7 through 10 are cross-sectional views taken along line A-A′ of FIGS. 5 and 6 and line B-B′ of FIG. 5; and

FIGS. 11 through 24 are intermediate step diagrams of methods for manufacturing semiconductor devices according to some embodiments of the present disclosure.

### DETAILED DESCRIPTION

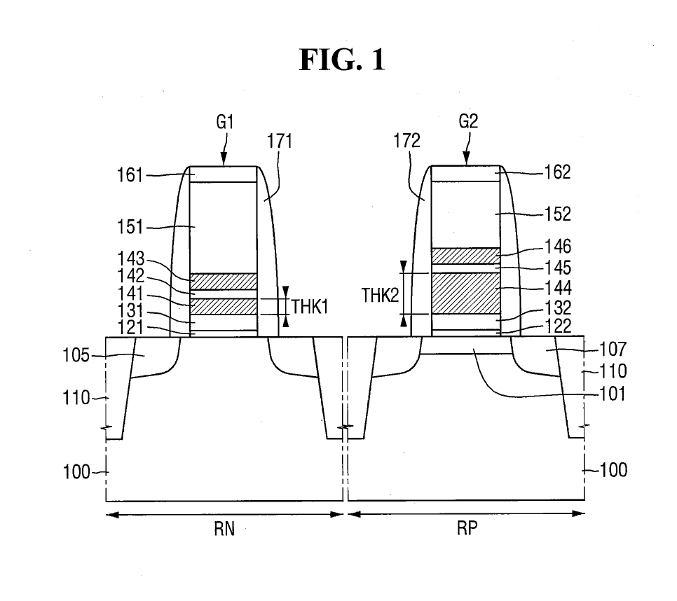

A semiconductor device according to some aspects of the present disclosure will be described with reference to FIG. 1.

FIG. 1 is a cross-sectional view of a semiconductor device according to some aspects of the present disclosure.

Referring to FIG. 1, the substrate 100 may include an NMOS region (RN) and a PMOS region (RP). The NMOS region (RN) and the PMOS region (RP) may be regions separated from each other, or may be regions connected to each other.

Transistors of different conductivity types may be disposed in each of the NMOS region (RN) and the PMOS region (RP). For example, an NMOS transistor may be formed in the NMOS region (RN). Further, a PMOS transistor may be formed in the PMOS region (RP).

The substrate 100 may be, for example, bulk silicon or silicon-on-insulator (SOI). Alternatively, the substrate 100 may be a silicon substrate or include other material, for example, silicon germanium, indium antimonide, lead tellurium compounds, indium arsenide, indium phosphide, gallium arsenide or gallium antimonide. Or, the substrate 100 may have an epitaxial layer formed on the base substrate.

The substrate 100 may include an element isolation film 110. A plurality of element isolation films 110 may be in the substrate 100. The element isolation film 110 is formed, for example, in the substrate 100, and may define the NMOS region (RN) and the PMOS region (RP), respectively. In addition, at least one transistor may be between the element isolation films 110 adjacent to each other among the element isolation films 110.

The element isolation film 110 may include silicon oxide, silicon nitride, or a combination thereof, but the present disclosure is not limited thereto. The element isolation film 110 may be a single layer made of one kind of insulating material, or may be multi-layers made of a combination of various kinds of insulating materials.

A first transistor may be disposed in the NMOS region (RN). The first transistor may include a first gate stack G1, a first gate spacer 171, and a first source/drain region 105. The first transistor may be an n-type planar transistor.

The first gate spacer 171 may be on at least one side of the first gate stack G1. For example, the first gate spacer 171, sidewalls thereof, or a plurality of first gate spacers 171 may be on both sides of the first gate stack G1.

The first gate spacer 171 may include, for example, at least one of silicon nitride (SiN), silicon oxynitride (SiON), silicon oxide (SiO₂), silicon oxycarbonitride (SiOCN), silicon carbonitride (SiCN) or any combination thereof.

The first gate stack G1 may include a first high-dielectric constant insulating film 131, a first gate electrode layer 141, a second gate electrode layer 142, a third gate electrode layer 143, and a first silicon layer 151 that may be sequentially laminated. The first gate electrode layer 141, the second gate electrode layer 142, the third gate electrode layer 143, and the first silicon layer 151 may be between sidewalls of the first gate spacer 171 or the first gate spacers 171, for example, when there is a plurality of first gate spacers 171.

In some embodiments, the first gate stack G1 may further include a first interfacial insulating film 121. The first interfacial insulating film 121 may be between the first high-dielectric constant insulating film 131 and the substrate 100. The first interfacial insulating film 121 may include a low-dielectric material layer having a dielectric constant (k) of 9 or less, for example, a silicon oxide film (k of about 4) or a silicon oxynitride film (k of about 4 to 8 in accordance with the content of oxygen atoms and nitrogen atoms).

In some embodiments, the first high-dielectric constant insulating film 131 may not extend between the respective sidewalls of the first gate spacer 171, the first gate electrode layer 141, the second gate electrode layer 142, and the third gate electrode layer 143. In some embodiments, the first high-dielectric constant insulating film 131 may disposed on the first interfacial insulating film 121 and extend partially between the respective sidewalls of the first gate spacer 171, the first gate electrode layer 141, the second gate electrode layer 142, and the third gate electrode layer 143.

The first high-dielectric constant insulating film 131 may include, for example, a high-dielectric constant (high-k dielectric) material having a dielectric constant higher than silicon. The first high-dielectric constant insulating film 131 may include, for example, hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO) or lead scandium tantalum oxide (PbScTaO) or a combination thereof, but the present disclosure is not limited thereto.

The first gate electrode layer 141 may be on the first high-dielectric constant insulating film 131. For example, the first gate electrode layer 141 may be directly on the first high-dielectric constant insulating film 131. Therefore, in some embodiments, another layer may not be interposed between the first high-dielectric constant insulating film 131 and the first gate electrode layer 141.

The first gate electrode layer 141 may have a first thickness THK1. Here, the first thickness THK1 may be a value measured in a direction perpendicular to the top surface of the substrate 100. For example, the first thickness THK1 may be a value obtained by measurement from a boundary between the first high-dielectric constant insulating film 131 and the first gate electrode layer 141 to a boundary between the first gate electrode layer 141 and the second gate electrode layer 142.

The first gate electrode layer 141 may include, for example, one of a titanium element or a tantalum element. In some embodiments, the first gate electrode layer 141 may include one of titanium nitride or tantalum nitride.

The second gate electrode layer 142 may be on the first gate electrode layer 141. The second gate electrode layer 142 may be, for example, directly on the first gate electrode layer 141. Therefore, in some embodiments, another layer may not be interposed between the first gate electrode layer 141 and the second gate electrode layer 142.

The second gate electrode layer 142 may include, for example, a lanthanum-based material. The second gate electrode layer 142 may include, for example, a lanthanum element. In some embodiments, the second gate electrode layer 142 may include at least one of a lanthanum film, a lanthanum oxide film, a lanthanum nitride film, and a lanthanum oxynitride film.

Although the thickness of the second gate electrode layer 142 is illustrated to be smaller than the first thickness THK1 in FIG. 1, the present disclosure is not limited thereto. The thickness of the second gate electrode layer 142 may be varied, depending on the manufacturing process of the semiconductor device.

The third gate electrode layer 143 may be on the second gate electrode layer 142. The third gate electrode layer 143 may be, for example, directly on the second gate electrode layer 142. Therefore, in some embodiments, another layer may not be interposed between the second gate electrode layer 142 and the third gate electrode layer 143.

The third gate electrode layer 143 may include, for example, one of a titanium element or a tantalum element. In some embodiments, the third gate electrode layer 143 may include titanium nitride. However, the present disclosure is not limited thereto. For example, the third gate electrode layer 143 may include TiSiN, tungsten, tungsten silicide, or a combination thereof.

The first silicon layer 151 may be on the third gate electrode layer 143. The first silicon layer 151 may be, for example, directly on the third gate electrode layer 143. Therefore, in some embodiments, another layer may not be interposed between the first silicon layer 151 and the third gate electrode layer 143.

The first silicon layer 151 may include, for example, polysilicon.

In some embodiments, the first gate stack G1 may further include a first hard mask pattern 161. The first hard mask pattern 161 may be disposed on the first silicon layer 151. The first hard mask pattern 161 may include, for example, silicon nitride, but the present disclosure is not limited thereto.

The first source/drain region 105 may be on at least one side of the first gate stack G1. The first source/drain region 105 may be, for example, in the substrate 100. The first source/drain region 105 may contain impurities implanted in a partial region of the substrate 100. For example, the first source/drain region 105 may include the same material as the material included in the substrate 100 or a tensile stress material. For example, when the substrate 100 is Si, the first source/drain region 105 may contain Si or a material (e.g., SiC) having a smaller lattice constant than Si.

The first channel region may be a partial region in the substrate 100 located under the first gate stack G1 and between the first source/drain regions 105. The first channel region may include, for example, the same material as that included in the substrate 100.

A second transistor may be disposed in the PMOS region (RP). The second transistor may include a second gate stack G2, a second gate spacer 172 or second gate spacers 172, and a second source/drain region 107. The second transistor may be a p-type planar transistor.

The second gate spacer 172 may be on at least one side of the second gate stack G2. For example, second gate spacers 172 may be on both sides of the second gate stack G2. The second gate spacer 172 or second gate spacers 172 may include, for example, the same material as that of the first gate spacer 171 or first gate spacers 171.

The second gate stack G2 may include a second high-dielectric constant insulating film 132, a fourth gate electrode layer 144, a fifth gate electrode layer 145, a sixth gate electrode layer, and a second silicon layer 152 that are sequentially laminated. The fourth gate electrode layer 144, the fifth gate electrode layer 145, the sixth gate electrode layer 146, and the second silicon layer 152 are between the second gate spacers 172.

In some embodiments, the second gate stack G2 may further include a second interfacial insulating film 122. The second interfacial insulating film 122 may be between the second high-dielectric constant insulating film 132 and the substrate 100. The second interfacial insulating film 122 may include, for example, the same material as that of the first interfacial insulating film 121.

In some embodiments, the second high-dielectric constant insulating film 132 may extend between the sidewalls of each of the second gate spacer 172 or second gate spacers 172, the fourth gate electrode layer 144, the fifth gate electrode layer 145, and the sixth gate electrode layer 146. In some embodiments, the second high-dielectric constant insulating film 132 may disposed on the second interfacial insulating film 122 and extend partially between the sidewalls of each of the second gate spacer 172 or second gate spacers 172, the fourth gate electrode layer 144, the fifth gate electrode layer 145, and the sixth gate electrode layer 146. The second high-dielectric constant insulating film 132 may include, for example, the same material as the first high-dielectric constant insulating film 131. The second high-dielectric constant insulating film 132 may be formed, for example, at the same level as the first high-dielectric constant insulating film 131. Herein, the term “the same level” may mean a level formed by the same manufacturing process.

The fourth gate electrode layer 144 may be on the second high-dielectric constant insulating film 132. The fourth gate electrode layer 144 may be, for example, directly on the second high-dielectric constant insulating film 132. Therefore, in some embodiments, another layer may not be interposed between the second high-dielectric constant insulating film 132 and the fourth gate electrode layer 144.

The fourth gate electrode layer 144 may have a second thickness THK2. Here, the second thickness THK2 may be value measured in the direction perpendicular to the top surface of the substrate 100. For example, the second thickness THK2 may be a value measured from the boundary between the second high-dielectric constant insulating film 132 and the fourth gate electrode layer 145 to the boundary between the fourth gate electrode layer 144 and the fifth gate electrode layer 144. In some embodiments, the second thickness THK2 of the fourth gate electrode layer 144 may be greater than the first thickness THK1 of the first gate electrode layer 141.

The fourth gate electrode layer 144 may include, for example, one of a titanium element and a tantalum element. In some embodiments, the fourth gate electrode layer 144 may include the same metal element as the metal element included in the first gate electrode layer 141. In some embodiments, the fourth gate electrode layer 144 may include one of titanium nitride and tantalum nitride.

The fifth gate electrode layer 145 may be on the fourth gate electrode layer 144. The fifth gate electrode layer 145 may be, for example, directly on the fourth gate electrode layer 144. Therefore, in some embodiments, another layer may not be interposed between the fourth gate electrode layer 144 and the fifth gate electrode layer 145.

The fifth gate electrode layer 145 may include, for example, a lanthanum-based material. The fifth gate electrode layer 145 may include, for example, a lanthanum element. In some embodiments, the fifth gate electrode layer 145 may include at least one of a lanthanum film, a lanthanum oxide film, a lanthanum nitride film, and a lanthanum oxynitride film. In some embodiments, the fifth gate electrode layer 145 may include the same material as the second gate electrode layer 142. In this case, the fifth gate electrode layer 145 may be formed at the same level as the second gate electrode layer 142.

The sixth gate electrode layer 146 may be on the fifth gate electrode layer 145. The sixth gate electrode layer 146 may be, for example, directly on the fifth gate electrode layer 145. Therefore, in some embodiments, another layer may not be interposed between the fifth gate electrode layer 145 and the sixth gate electrode layer 146.

The sixth gate electrode layer 146 may include, for example, either a titanium element or a tantalum element. In some embodiments, the sixth gate electrode layer 146 may contain titanium nitride. However, the present disclosure is not limited thereto. For example, the sixth gate electrode layer 146 may include TiSiN, tungsten, tungsten silicide, or a combination thereof. In some embodiments, the sixth gate electrode layer 146 may include the same material as the third gate electrode layer 143. In this case, the sixth gate electrode layer 146 may be formed at the same level as the third gate electrode layer 143.

The second silicon layer 152 may be on the sixth gate electrode layer 146. The second silicon layer 152 may be, for example, directly on the sixth gate electrode layer 146. Thus, in some embodiments, another layer may not be interposed between the second silicon layer 152 and the sixth gate electrode layer 146.

The second silicon layer 152 may include, for example, the same material as the first silicon layer 151. In this case, the second silicon layer 152 may be formed at the same level as the first silicon layer 151.

In some embodiments, the second gate stack G2 may further include a second hard mask pattern 162. The second hard mask pattern 162 may be on the second silicon layer 152. The second hard mask pattern 162 may include the same material as the first hard mask pattern 161. In this case, the second hard mask pattern 162 may be formed at the same level as the first hard mask pattern 161.

The second source/drain region 107 may be on at least one side of the second gate stack G2. The second source/drain region 107 may be, for example, inside the substrate 100. The second source/drain region 107 may contain impurities implanted in a partial region of the substrate 100.

The second channel region 101 may be inside the substrate 100 for the second transistor, i.e., a p-type transistor. The second channel region 101 may include a material different from that of the first channel region. The second channel region 101 may include, for example, a germanium element. In some embodiments, the second channel region 101 may include silicon germanium (SiGe).

The first gate electrode layer 141 of the semiconductor device according to some embodiments of the present disclosure may be between the first high-dielectric constant insulating film 131 and the second gate electrode layer 142, and the fourth gate electrode layer 144 may be between the second high-dielectric constant insulating film 132 and the fifth gate electrode layer 145. Because of the arrangement of the first gate electrode layer 141 and the fourth gate electrode layer 144, the total thickness of the oxide film included in the transistor may be reduced. For example, when the second gate electrode layer 142 and the fifth gate electrode layer 145 contain lanthanum oxide, since the first gate electrode layer 141 and the fourth gate electrode layer 144 of the semiconductor device, according to some embodiments of the present disclosure, may be between the layer containing the lanthanum oxide and the layer containing the high-dielectric constant material, the total thickness of the oxide layer of the transistor is not increased even if a part remains after the lanthanum oxide is diffused into the layer containing the high-dielectric constant material.

Further, for example, when the second gate electrode layer 142 contains lanthanum oxide, it may possible to reduce or inhibit the influence of the second gate electrode layer 142 on the threshold value of the transistor in the NMOS region (RN) of the semiconductor device, according to some embodiments of the present disclosure. For example, the lanthanum oxide may lower the threshold voltage of the transistor in the NMOS region (RN). At this time, the threshold voltage of the transistor in the NMOS region (RN) may be susceptible to the thickness of the layer containing the lanthanum oxide. In a case where the threshold voltage of the transistor in the NMOS region (RN) changes in accordance with the thickness of the layer containing the lanthanum oxide, there may be a problem in the reliability of the semiconductor device. Since the first gate electrode layer 141 of the device may be between the second gate electrode layer 142 and the first high-dielectric constant insulating film 131, it may be possible to reduce the degree to which the threshold voltage of the transistor in the NMOS region (RN) is susceptible to the thickness of the layer containing the lanthanum oxide.

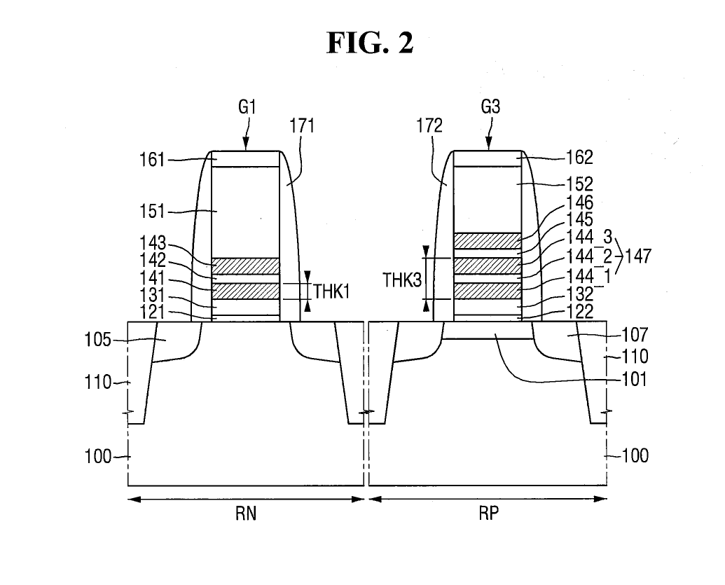

A semiconductor device according to some aspects of the present disclosure will be described with reference to FIG. 2. For the sake of convenience of explanation, redundant description will not be provided. FIG. 2 is a cross-sectional view illustrating a semiconductor device according to some aspects of the present disclosure.

Referring to FIG. 2, a first transistor including the first gate stack G1, the first gate spacer 171, and the first source/drain region 105 of FIG. 1 may be disposed in the NMOS region (RN) of the substrate 100.

A third transistor may be disposed in the PMOS region (RP) of the substrate 100. The third transistor may include a third gate stack G3, a second gate spacer 172, and a second source/drain region 107. The third transistor may be a p-type planar transistor.

The third gate stack G3 may include a second high-dielectric constant insulating film 132, a seventh gate electrode layer 147, a fifth gate electrode layer 145, a sixth gate electrode layer 146, and a second silicon layer 152 which may be sequentially laminated. The seventh gate electrode layer 147, the fifth gate electrode layer 145, the sixth gate electrode layer 146, and the second silicon layer 152 may be between the second gate spacers 172.

In some embodiments, the second high-dielectric constant insulating film 132 may not extend between the sidewalls of each of the second gate spacer 172, the seventh gate electrode layer 147, the fifth gate electrode layer 145, and the sixth gate electrode layer 146. In some embodiments, the second high-dielectric constant insulating film 132 may extend partially between the sidewalls of each of the second gate spacer 172, the seventh gate electrode layer 147, the fifth gate electrode layer 145, and the sixth gate electrode layer 146.

The seventh gate electrode layer 147, the fifth gate electrode layer 145, the sixth gate electrode layer 146, and the second silicon layer 152 may be between the second gate spacers 172. The seventh gate electrode layer 147 may include a first metal layer 144_1, a second metal layer 144_2, and a third metal layer 144_3 that may be sequentially laminated. The second metal layer 144_2 may be directly on the first metal layer 144_1, and the third metal layer 144_3 may be directly on the second metal layer 14_2.

The thickness of the seventh gate electrode layer 147 may be a third thickness THK3. The third thickness THK3 may be a value measured from a boundary between the second high-dielectric constant insulating film 132 and the first metal layer 144_1 to a boundary between the third metal layer 144_3 and the fifth gate electrode layer 145. The third thickness THK3 may be larger than the first thickness THK1.

In some embodiments, the first metal layer 144_1 and the third metal layer 144_3 may include the same metal material. Alternatively, in some embodiments, each of the first metal layer 144_1 and the third metal layer 144_3 may include either a titanium element or a tantalum element.

The second metal layer 144_2 may include a material different from the material included in the first metal layer 144_1 and the third metal layer 144_3. For example, the second metal layer 144_2 may include an aluminum element.

The fifth gate electrode layer 145 may be directly on the third metal layer 144_3.

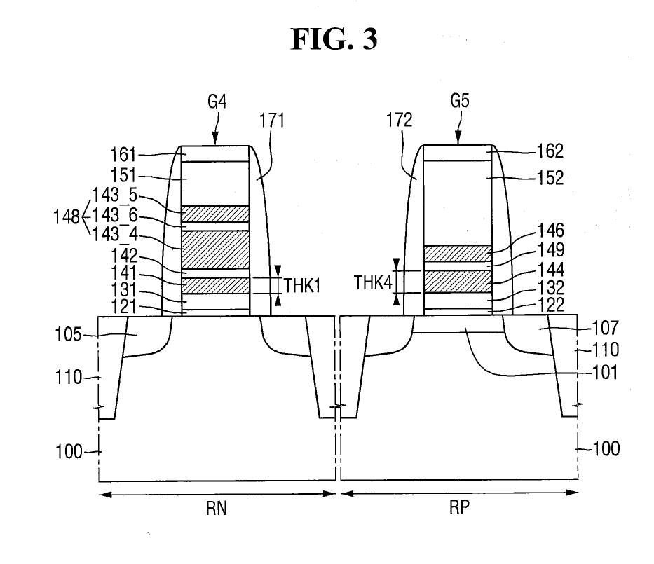

A semiconductor device according to some aspects of the present disclosure will be described with reference to FIG. 3. For the sake of convenience of explanation, redundant description will not be provided.

FIG. 3 is a cross-sectional view illustrating a semiconductor device according to some aspects of the present disclosure.

Referring to FIG. 3, a fourth transistor may be disposed in the NMOS region (RN). The fourth transistor may include a fourth gate stack G4, a first gate spacer 171, and a first source/drain region 105. The fourth transistor may be an n-type planar transistor.

The fourth gate stack G4 may include a first high-dielectric constant insulating film 131, a first gate electrode layer 141, a second gate electrode layer 142, an eighth gate electrode layer 148, and a first silicon layer 151 that may be sequentially laminated. The first gate electrode layer 141, the second gate electrode layer 142, the eighth gate electrode layer 148, and the first silicon layer 151 may be between the first gate spacers 171, for example where there is a plurality of first gate spacers 171.

In some embodiments, the first high-dielectric constant insulating film 131 may not extend between sidewalls of each of the first gate spacer 171 or first gate spacers 171, the first gate electrode layer 141, the second gate electrode layer 142, and the eighth gate electrode layer 148. In some embodiments, the first high-dielectric constant insulating film 131 may extend partially between sidewalls of each of the first gate spacer 171 or first gate spacers 171, the first gate electrode layer 141, the second gate electrode layer 142, and the eighth gate electrode layer 148.

The eighth gate electrode layer 148 may be on the second gate electrode layer 142. The eighth gate electrode layer 148 may be, for example, directly on the second gate electrode layer 142. Thus, in some embodiments, no other layer may be interposed between the second gate electrode layer 142 and the eighth gate electrode layer 148.

The eighth gate electrode layer 148 may include a fourth metal layer 143_4, a fifth metal layer 143_5, and a sixth metal layer 143_6. The sixth metal layer 143_6 may be interposed between the fourth metal layer 143_4 and the fifth metal layer 143_5. The sixth metal layer 143_6 may be directly on the fourth metal layer 143_4, and the fifth metal layer 143_5 may be directly on the sixth metal layer 143_6.

In some embodiments, the fourth metal layer 143_4 and the fifth metal layer 143_5 may include the same metal material. Alternatively, in some embodiments, each of the fourth metal layer 143_4 and the fifth metal layer 143_5 may include either a titanium element or a tantalum element.

The sixth metal layer 143_6 may include a material different from the material included in the fourth metal layer 143_4 and the fifth metal layer 143_5. For example, the sixth metal layer 143_6 may contain an aluminum element.

A fifth transistor may be in the PMOS region (RP) of the substrate 100. The fifth transistor may include a fifth gate stack G5, a second gate spacer 172, and a second source/drain region 107. The fifth transistor may be a p-type planar transistor.

The fifth gate stack G5 may include a second high-dielectric constant insulating film 132, a fourth gate electrode layer 144, a ninth gate electrode layer 149, a sixth gate electrode layer 146, and a second silicon layer 152 which are sequentially laminated. The fourth gate electrode layer 144, the ninth gate electrode layer 149, the sixth gate electrode layer 146, and the second silicon layer 152 may be between the second gate spacers 172.

In some embodiments, the second high-dielectric constant insulating film 132 may not extend between sidewalls of each of the second gate spacer 172, the fourth gate electrode layer 144, the ninth gate electrode layer 149, and the sixth gate electrode layer 146.

The fourth gate electrode layer 144 may have a fourth thickness THK4. The fourth gate electrode layer 144 of the second gate stack G2 of FIG. 1 may be substantially the same as the fourth gate electrode layer 144 of FIG. 3. However, the fourth thickness THK4 of the fourth gate electrode layer 144 of FIG. 3 may be smaller than the second thickness THK2 of the fourth gate electrode layer 144 of FIG. 1.

The ninth gate electrode layer 149 may be directly on the fourth gate electrode layer 144. The ninth gate electrode layer 149 may include, for example, the same material as that included in the sixth metal layer 143_6. The ninth gate electrode layer 149 may be formed, for example, at the same level as that of the sixth metal layer 143_6.

The sixth gate electrode layer 146 may be directly on the ninth gate electrode layer 149.

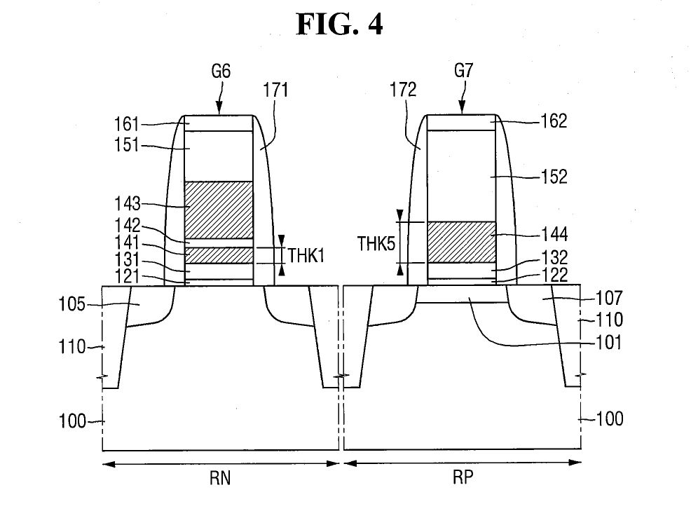

A semiconductor device according to some aspects of the present disclosure will be described with reference to FIG. 4. For the sake of convenience of explanation, redundant description will not be provided.

FIG. 4 is a cross-sectional view illustrating a semiconductor device according to some aspects of the present disclosure.

Referring to FIG. 4, a sixth transistor may be disposed in the NMOS region (RN) of the substrate 100. The sixth transistor may include a sixth gate stack G6, a first gate spacer 171, and a first source/drain region 105. The sixth transistor may be an n-type planar transistor.

The sixth gate stack G6 may include a first high-dielectric constant insulating film 131, a first gate electrode layer 141, a second gate electrode layer 142, a third gate electrode layer 143, and a first silicon layer 151 which may be sequentially laminated. The first gate electrode layer 141, the second gate electrode layer 142, the third gate electrode layer 143, and the first silicon layer 151 may be interposed between the first gate spacers 171.

In some embodiments, the first high-dielectric constant insulating film 131 may not extend between sidewalls of each of the first gate spacer 171, the first gate electrode layer 141, the second gate electrode layer 142, and the third gate electrode layer 143. In some embodiments, the first high-dielectric constant insulating film 131 may extend partially between sidewalls of each of the first gate spacer 171, the first gate electrode layer 141, the second gate electrode layer 142, and the third gate electrode layer 143.

The third gate electrode layer 143 may be substantially the same as the third gate electrode layer 143 of FIG. 1. However, the thickness of the third gate electrode layer 143 of FIG. 4 may be thicker than the thickness of the third gate electrode layer 143 of FIG. 1.

A seventh transistor may be disposed in the PMOS region (RP) of the substrate 100. The seventh transistor may include a seventh gate stack G7, a second gate spacer 172, and a second source/drain region 107. The seventh transistor may be a p-type planar transistor.

The seventh gate stack G7 may include a second high-dielectric constant insulating film 132, a fourth gate electrode layer 144, and a second silicon layer 152 which may be sequentially laminated. The fourth gate electrode layer 144 and the second silicon layer 152 may be between the second gate spacers 172.

In some embodiments, the second high-dielectric constant insulating film 132 may not extend between the sidewalls of each of the second gate spacer 172, the fourth gate electrode layer 144, and the second silicon layer 152. In some embodiments, the second high-dielectric constant insulating film 132 may extend partially between the sidewalls of each of the second gate spacer 172, the fourth gate electrode layer 144, and the second silicon layer 152.

The fourth gate electrode layer 144 may have a fifth thickness THK5. The fourth gate electrode layer 144 of the second gate stack G2 of FIG. 1, the fourth gate electrode layer 144 of FIG. 3, and the fourth gate electrode layer 144 of FIG. 4 may be substantially the same. The fifth thickness THK5 of the fourth gate electrode layer 144 may be substantially the same as the second thickness THK2 of the fourth gate electrode layer 144 of FIG. 1. However, the present disclosure is not limited thereto. For example, the fifth thickness THK5 of the fourth gate electrode layer 144 may be different from the second thickness THK2 of the fourth gate electrode layer 144 of FIG. 1.

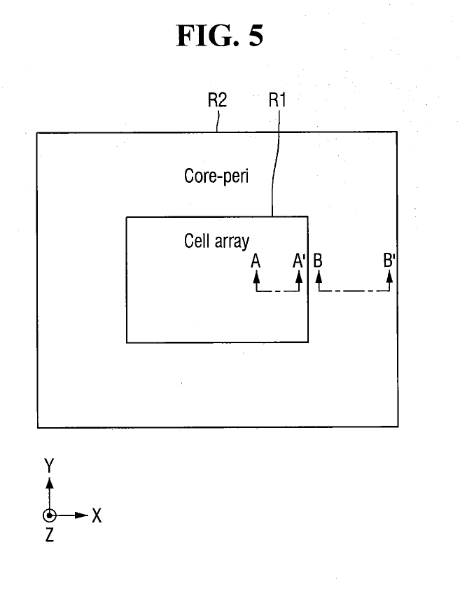

A semiconductor device according to some aspects of the present disclosure will be described with reference to FIGS. 5 to 7. For the sake of convenience of explanation, redundant description will not be provided.

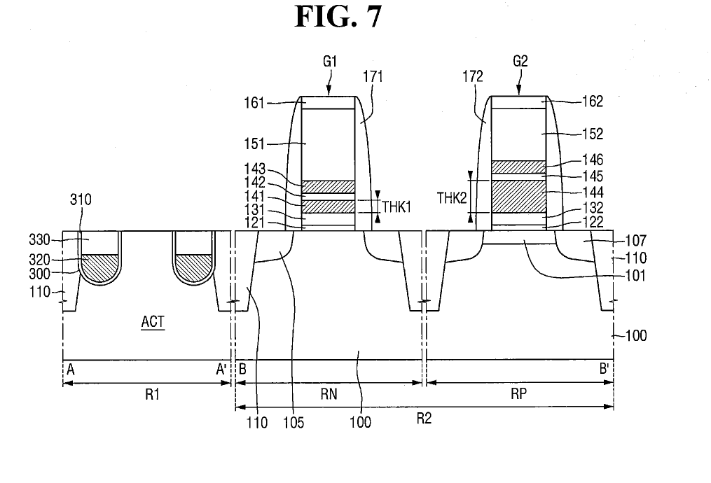

FIG. 5 is a plan view of a substrate 100 in FIG. 7 of a semiconductor device according to some aspects of the present disclosure.

Referring to FIG. 5, the substrate (100 of FIG. 7) may include a first region R1 and a second region R2. The first region R1 may be surrounded by the second region R2. For example, the second region R2 may surround the first region R1 in a plan view of a horizontal plane formed by the first direction X and the second direction Y. The first region R1 may be a cell array region. The second region R2 may be a peripheral region or a core-peri region. The first region R1 may be a region in which the memory cells of the memory device are arranged. The second region R2 may be a region which surrounds the memory cell region and in which transistors for controlling the operation of the memory cells are formed.

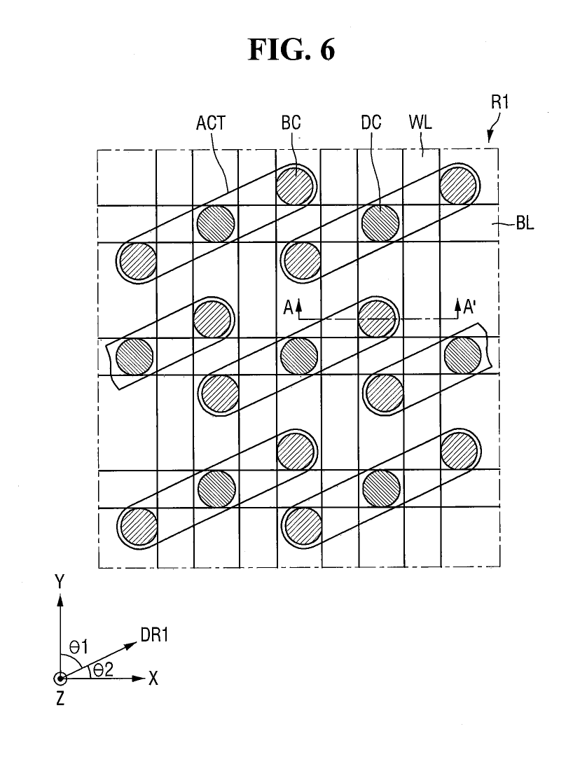

FIG. 6 is an enlarged view of the first region R1 of FIG. 5.

Referring to FIG. 6, the first region R1 may include a word line WL, a bit line BL, a storage node contact BC, a bit line contact DC and the like.

The active region ACT may be formed to extend in the fourth direction DR1, and the word line WL may be formed to extend in a second direction Y which forms a first acute angle θ1 with the fourth direction DR1, and the bit line BL may be formed to extend in a first direction X which forms a second acute angle θ2 with the fourth direction DR1.

When two lines intersect, two pairs of supplementary angles are formed. Here, the angle in the case where “a specific direction and another specific direction form a predetermined angle” may mean a smaller angle among the two angles of a given pair of supplementary angles generated by the intersection between the two directions. For example, if the angles that may occur by the intersection between the two directions are 120° and 60°, the angle referred to herein may be the 60° acute angle. Therefore, as illustrated in FIG. 6, the angle formed by the fourth direction DR1 and the second direction Y may be the first acute angle θ1, and the angle formed by the fourth direction DR1 and the first direction X may be the second acute angle θ2.

The first acute angle θ1 and/or the second acute angle θ2 may form an acute angle to enhance the degree of integration of the memory cells. That is, the first acute angle θ1 and/or the second acute angle θ2 may be acute to secure the interval between the bit line BL, the active region ACT, and the storage node contact BC connecting the capacitors, while reducing the size of the active region ACT. The first acute angle θ1 and the second acute angle θ2 may be, for example, but are not limited to, 45°, 45°, or 30°, 60°, or 60°, 30°, respectively.

A semiconductor device according to some aspects of the present disclosure may be in the form of a memory cell. In FIG. 7, a dynamic random access memory cell (DRAM) is illustrated as an example of the memory cell, but the present disclosure is not limited thereto.

FIG. 7 is a cross-sectional view taken along the line A-A′ of FIGS. 5 and 6, and the line B-B′ of FIG. 5. In FIG. 7, for clarity, only the word line (WL) 320 is illustrated.

Referring to FIG. 7, a buried gate trench 300 may be formed inside the first region R1 of the substrate 100. The buried gate trench 300 may abut on the element isolation film 110. The buried gate trench 300 may be formed by etching a part of the element isolation film 110, but the present disclosure is not limited thereto.

A buried gate insulating film 310 may be formed along the bottom surface and the side surface of the buried gate trench 300. The buried gate insulating film 310 may include at least one of a silicon oxide film, a silicon nitride film, a silicon oxynitride film, or a high-dielectric constant material. For example, the high-dielectric constant material may include HfO2, HfSiO4, HfAlO, ZrO2, ZrSiO4, TaO2, Ta2O5, and Al2O3, but the present disclosure is not limited thereto.

A buried gate electrode 320 may be on the buried gate insulating film 310 to fill a part of the buried gate trench 300. The buried gate electrode 320 may include a conductive material, for example, tungsten or titanium nitride. The buried gate electrode 320 may also include multi-films including, for example, tungsten or titanium nitride, respectively. At this time, the buried gate electrode 320 may be the same constituent element as a word line (WL of FIG. 6).

A buried gate capping film 330 may fill the remaining part of the buried gate trench 300 which may be left after the buried gate electrode 320 and the buried gate insulating film 310 are filled. The buried gate capping film 330 may be on the buried gate electrode 320. At this time, the side surface of the buried gate capping film 330 may be disposed on the buried gate insulating film 310.

As a result, a buried gate array structure (BCAT: buried cell array transistor) including the buried gate trench 300, the buried gate insulation film 310, the buried gate electrode 320, and the buried gate capping film 330 may be formed.

The second region R2 of the substrate 100 may include an NMOS region (RN) and a PMOS region (RP). In some embodiments, the first transistor and the second transistor described with reference to FIG. 1 may be in the second region R2 of the substrate 100. The first transistor and the second transistor of FIG. 1 may control the operation of the memory cell of the first region R1.

A semiconductor device according to some aspects of the present disclosure will be described with reference to FIGS. 5, 6 and 8. For the sake of convenience of explanation, redundant description will not be provided.

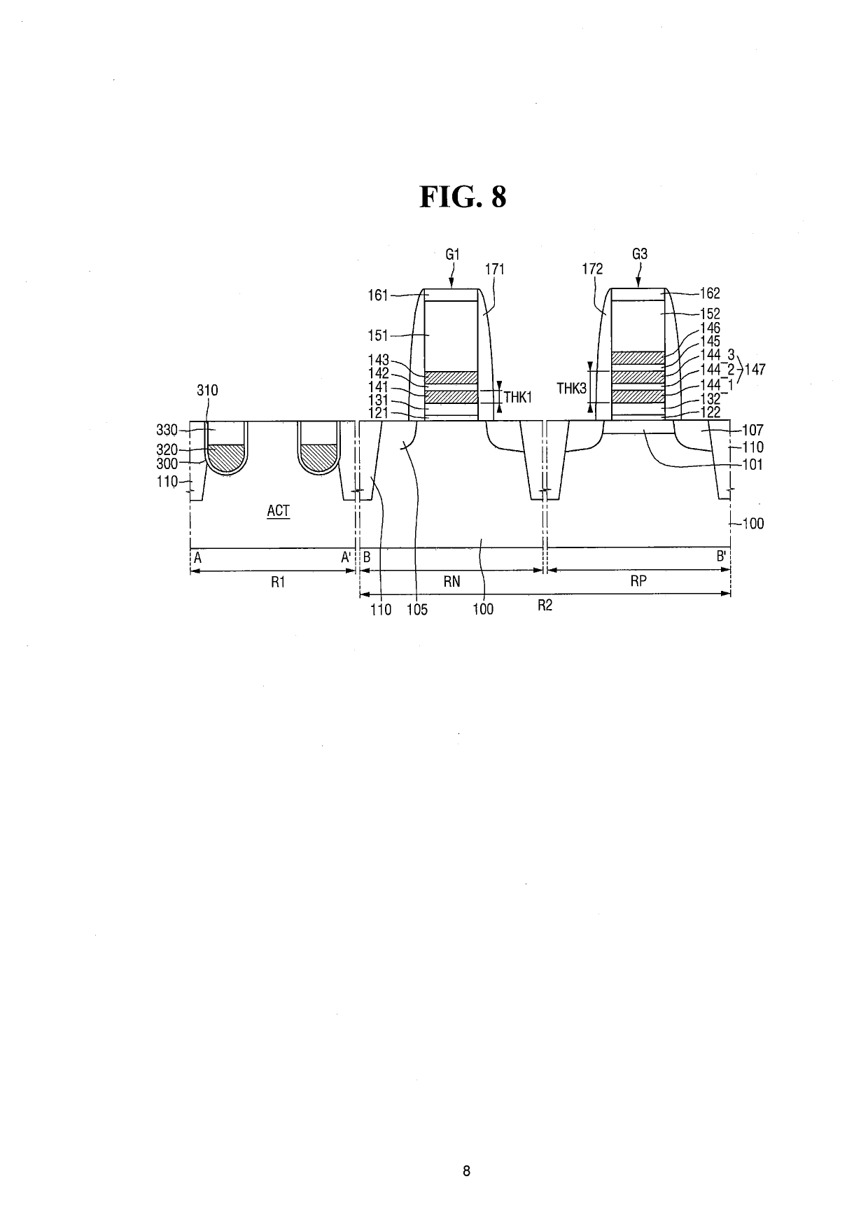

FIG. 8 is a cross-sectional view taken along line A-A′ of FIGS. 5 and 6 and line B-B′ of FIG. 5. For clarity, FIG. 8 illustrates only the word line (WL) 320.

Referring to FIGS. 5, 6, and 8, the buried gate structure described with reference to FIG. 7 may be in the first region R1 of the substrate 100. Further, the first transistor and the third transistor described with reference to FIG. 2 may be arranged in the second region R2 of the substrate 100. The first transistor and the third transistor of FIG. 2 may control the operation of the memory cell of the first region R1.

Semiconductor devices according to some aspects of the present disclosure will be described with reference to FIGS. 5, 6 and 9. For the sake of convenience of explanation, redundant description will not be provided.

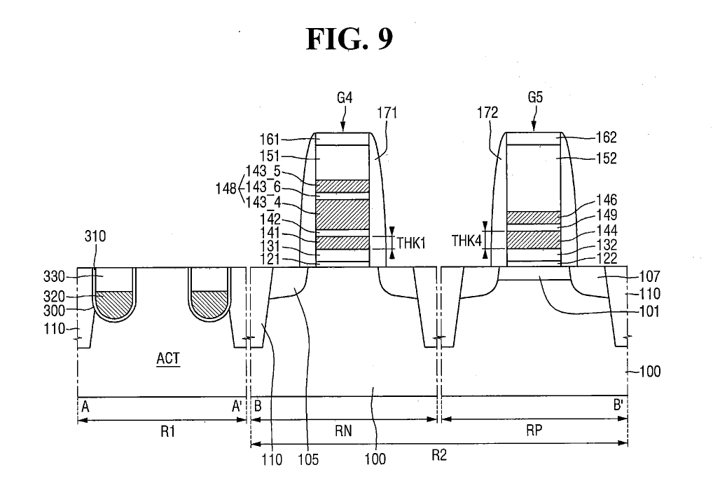

FIG. 9 is a cross-sectional view taken along the line A-A′ of FIGS. 5 and 6 and the line B-B′ of FIG. 5. For clarity, FIG. 9 illustrates only the word line (WL) 320.

Referring to FIGS. 5, 6, and 9, the buried gate structure described with reference to FIG. 7 may be in the first region R1 of the substrate 100. Further, the fourth transistor and the fifth transistor described with reference to FIG. 3 may be in the second region R2 of the substrate 100. The fourth transistor and the fifth transistor of FIG. 3 may control the operation of the memory cell of the first region R1.

Semiconductor devices according to some aspects of the present disclosure will be described with reference to FIGS. 5, 6 and 10. For the sake of convenience of explanation, redundant description will not be provided.

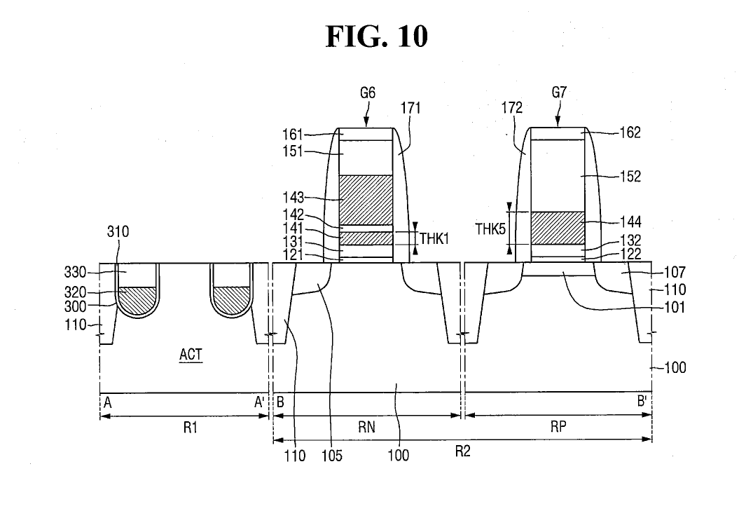

FIG. 10 is a cross-sectional view taken along line A-A′ of FIGS. 5 and 6 and line B-B′ of FIG. 5. For clarity, FIG. 10 illustrates only the word line (WL) 320.

Referring to FIGS. 5, 6, and 10, the buried gate structure described with reference to FIG. 7 may be in the first region R1 of the substrate 100. Further, the sixth transistor and the seventh transistor described with reference to FIG. 4 may be in the second region R2 of the substrate 100. The sixth transistor and the seventh transistor of FIG. 4 may control the operation of the memory cell of the first region R1.

A method for manufacturing one or more semiconductor devices according to some aspects of the present disclosure will be described with reference to FIGS. 1 and 11 through 14. For the sake of clear description, redundant description will not be provided.

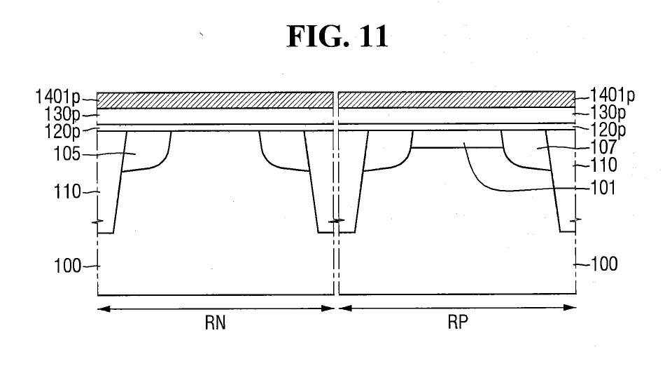

FIGS. 11 through 14 are intermediate step diagrams of a method for manufacturing one or more semiconductor devices according to some aspects of the present disclosure.

Referring to FIG. 11, the substrate 100 including the first channel region, the second channel region 101, the element isolation film 110, the first source/drain region 105, and the second source/drain region 107 may be provided.

A pre-interfacial insulating film 120p, a pre-high dielectric constant insulating film 130p, and a first pre-gate electrode layer 1401p may be formed to be sequentially laminated on the NMOS region (RN) and the PMOS region (RP) of the substrate 100.

The pre-interfacial insulating film 120p may include, for example, the same material as the first interfacial insulating film 121 described with reference to FIG. 1. The pre-high dielectric constant insulating film 130p may include, for example, the same material as the first high-dielectric constant insulating film 131 described with reference to FIG. 1. The first pre-gate electrode layer 1401p may include, for example, the same material as the first gate electrode layer 141 and the fourth gate electrode layer 144 described with reference to FIG. 1.

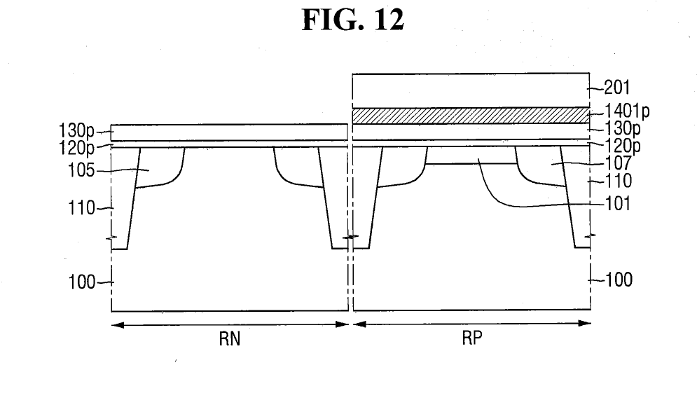

Referring to FIG. 12, the first mask 201 may be formed on the first pre-gate electrode layer 1401p of the PMOS region (RP) of the substrate 100. A portion of the first pre-gate electrode layer 1401p of the NMOS region (RN) which is not covered with the first mask 201 may be removed, by utilizing the etching selectivity of the pre-high dielectric constant insulating film 130p and the first pre-gate electrode layer 1401p.

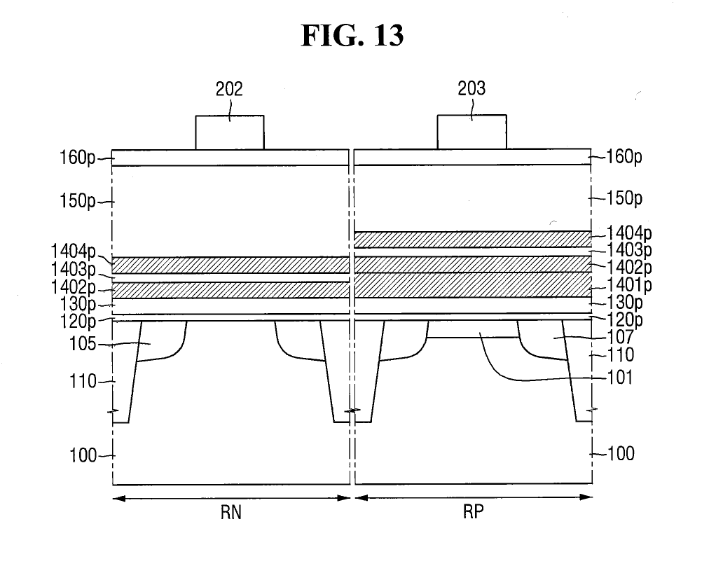

Referring to FIG. 13, after the first mask 201 of FIG. 12 is removed, a second pre-gate electrode layer 1402p, a third pre-gate electrode layer 1403p, a fourth pre-gate electrode layer 1404p, a pre-silicon layer 150p, and a pre-hard mask layer 160p may be sequentially laminated in the NMOS region (RN) and the PMOS region (RP), and thus, a laminated structure may be formed. Here, the laminated structure may include a pre-interfacial insulating film 120p and a pre-high dielectric constant insulating film 130p, in addition to the second pre-gate electrode layer 1402p, the third pre-gate electrode layer 1403p, the fourth pre-gate electrode layer 1404p, the pre-silicon layer 150p, and the pre-hard mask layer 160p of the NMOS region (RN) and the PMOS region (RP).

For example, a portion of the second pre-gate electrode layer 1402p formed in the NMOS region (RN) may be formed directly on the pre-high dielectric constant insulating film 130p. On the other hand, for example, a portion of the second pre-gate electrode layer 1402p formed in the PMOS region (RP) may be formed directly on the first pre-gate electrode layer 1401p. The first pre-gate electrode layer 1401p and the second pre-gate electrode layer 1402p may include, for example, the same material.

For example, a portion of the third pre-gate electrode layer 1403p formed in the NMOS region (RN) may be formed directly on the second pre-gate electrode layer 1402p. On the other hand, a portion of the third pre-gate electrode layer 1403p formed in the PMOS region (RP) may be formed, for example, directly on the second pre-gate electrode layer 1402p. The third pre-gate electrode layer 1403p may include, for example, the same material as the second gate electrode layer 142 and the fifth gate electrode layer 145 described with reference to FIG. 1.

The fourth pre-gate electrode layer 1404p formed in the NMOS region (RN) and the PMOS region (RP) may be, for example, formed directly on the third pre-gate electrode layer 1403p. The fourth pre-gate electrode layer 1404p may include, for example, the same material as those of the third gate electrode layer 143 and the sixth gate electrode layer 146 described with reference to FIG. 1.

The pre-silicon layer 150p formed in the NMOS region (RN) and the PMOS region (RP) may be formed, for example, directly on the fourth pre-gate electrode layer 1404p. The pre-silicon layer 150p may include, for example, the same material as those of the first silicon layer 151 and the second silicon layer 152 described with reference to FIG. 1.

The pre-hard mask layer 160p formed in the NMOS region (RN) and the PMOS region (RP) may be formed, for example, directly on the pre-silicon layer 150p. The pre-hard mask layer 160p may include, for example, the same material as those of the first hard mask pattern 161 and the second hard mask pattern 162 described with reference to FIG. 1.

A second mask 202 may be formed on the portion of the pre-hard mask layer 160p formed in the NMOS region (RN), and a third mask 203 may be formed on the portion of the pre-hard mask layer 160p formed in the PMOS region (RP).

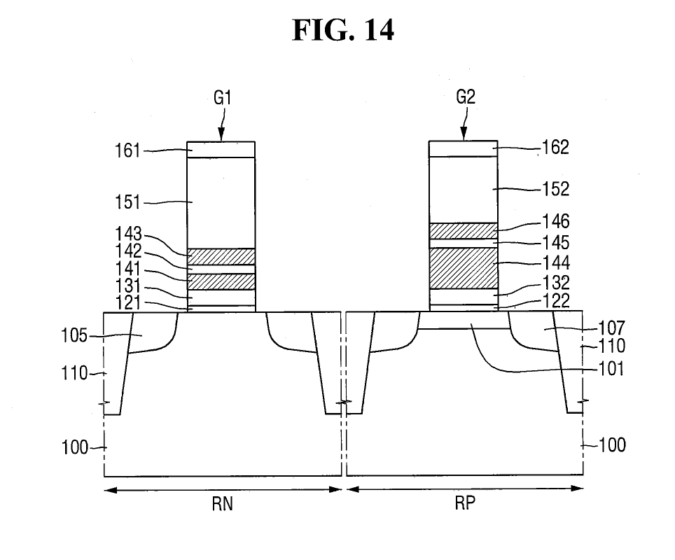

Referring to FIG. 14, a first gate stack G1 and a second gate stack G2 may be formed.

The first gate stack G1 may be formed by removing the portion of the laminated structure, which does not overlap the second mask 202 of FIG. 13, until the top surface of the substrate 100 is exposed. The second gate stack G2 may be formed by removing the portion of the laminated structure, which does not overlap the third mask 203 of FIG. 13, until the top surface of the substrate 100 is exposed.

For example, the first interfacial insulating film 121 of the NMOS region (RN) and the second interfacial insulating film 122 of the PMOS region (RP) may be formed by patterning the pre-interfacial insulating film 120p. The first high-dielectric constant insulating film 131 of the NMOS region (RN) and the second high-dielectric constant insulating film 132 of the PMOS region (RP) may be formed by patterning the pre-high dielectric constant insulating film 130p.

The first gate electrode layer 141 may be formed by patterning the second pre-gate electrode layer 1402p of the NMOS region (RN). The fourth gate electrode layer 144 may be formed by patterning the first pre-gate electrode layer 1401p and the second pre-gate electrode layer 1402p of the PMOS region (RP).

The second gate electrode layer 142 of the NMOS region (RN) and the fifth gate electrode layer 145 of the PMOS region (RP) may be formed by patterning the third pre-gate electrode layer 1403p. The third gate electrode layer 143 of the NMOS region (RN) and the sixth gate electrode layer 146 of the PMOS region may be formed by patterning the fourth pre-gate electrode layer 1404p. The first silicon layer 151 of the NMOS region (RN) and the second silicon layer 152 of the PMOS region (RP) may be formed by patterning the pre-silicon layer 150p. The first hard mask pattern 161 of the NMOS region (RN) and the second hard mask pattern 162 of the PMOS region (RP) may be formed by patterning the pre-hard mask layer 160p.

Referring to FIG. 1, a first gate spacer 171 may be formed on at least one side of the first gate stack G1. Further, a second gate spacer 172 may be formed on at least one side of the second gate stack G2.

A method for manufacturing one or more semiconductor devices according to some aspects of the present disclosure will be described with reference to FIGS. 2 and 15 through 18. For the sake of clear description, redundant description will not be provided.

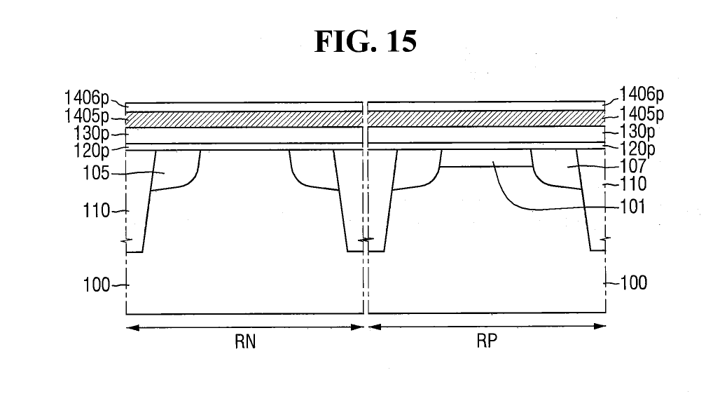

FIGS. 15 through 18 are intermediate step diagrams of a method for manufacturing one or more semiconductor devices according to some embodiments of the present inventive concept.

Referring to FIG. 15, a pre-interfacial insulating film 120p, a pre-high dielectric constant insulating film 130p, a fifth pre-gate electrode layer 1405p, and a sixth pre-gate electrode layer 1406p may be formed to be sequentially laminated on the NMOS region (RN) and the PMOS region (RP) of the substrate 100.

The fifth pre-gate electrode layer 1405p may include, for example, the same material as that of the first metal layer 144_1 described with reference to FIG. 2. The sixth pre-gate electrode layer 1406p may include, for example, the same material as that of the second metal layer 144_2 described with reference to FIG. 2.

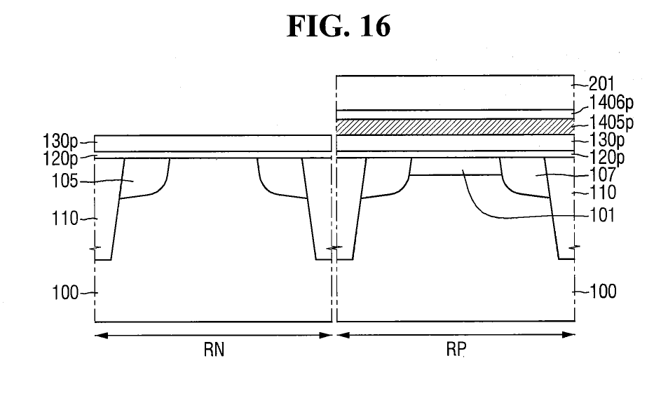

Referring to FIG. 16, the first mask 201 may be formed on the sixth pre-gate electrode layer 1406p of the PMOS region (RP) of the substrate 100. The portions of the fifth pre-gate electrode layer 1405p and the sixth pre-gate electrode layer 1406p of the NMOS region (RN) not covered with the first mask 201 may be removed, by utilizing the etching selectivity of the pre-high dielectric constant insulating films 130p, the fifth pre-gate electrode layer 1405p, and the sixth pre-gate electrode layer 1406p.

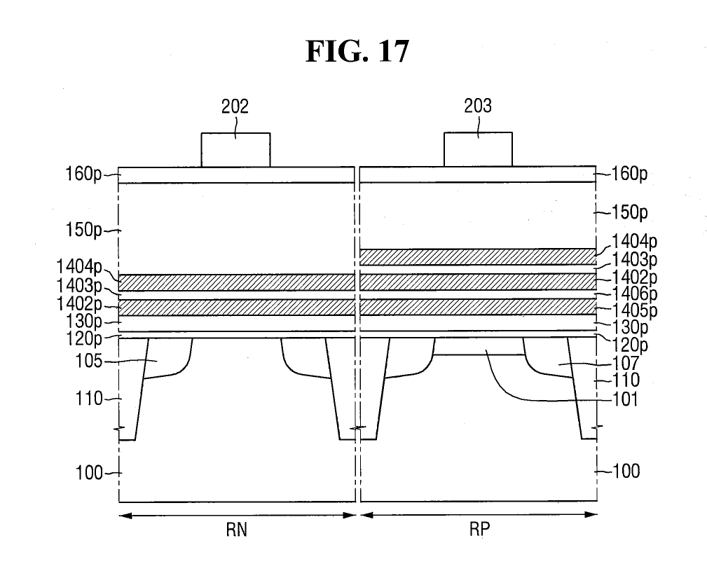

Referring to FIG. 17, after the first mask 201 of FIG. 16 is removed, the second pre-gate electrode layer 1402p, the third pre-gate electrode layer 1403p, the fourth pre-gate electrode layer 1404p, the pre-silicon layer 150p, and the pre-hard mask layer 160p are sequentially formed in the NMOS region (RN) and the PMOS region (RP), and thus, a laminated structure may be formed.

The portion of the second pre-gate electrode layer 1402p formed in the PMOS region (RP) may be formed directly on the sixth pre-gate electrode layer 1406p. The second pre-gate electrode layer 1402p may include, for example, the same material as those of the first gate electrode layer 141 and the third metal layer 144_3 described with reference to FIG. 2.

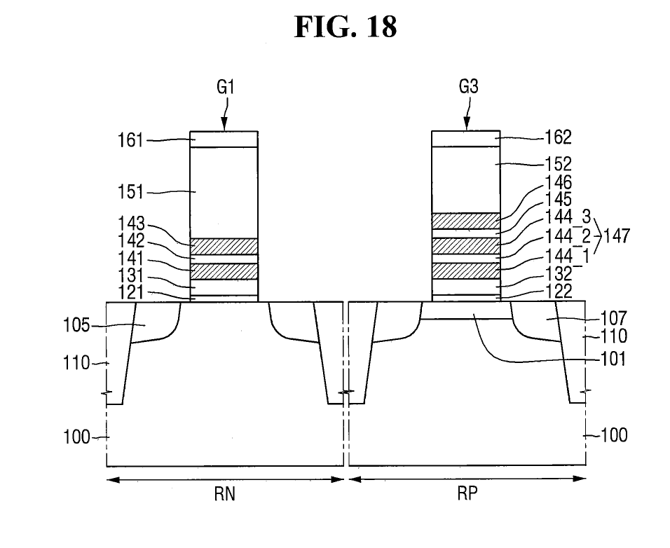

Referring to FIG. 18, a first gate stack G1 and a third gate stack G3 may be formed. The third gate stack G3 may be formed by removing the portion of the laminated structure, which does not overlap the third mask 203 of FIG. 17, until the top surface of the substrate 100 is exposed.

For example, the first metal layer 144_1 and the second metal layer 144_2 may be formed by patterning each of the fifth pre-gate electrode layer 1405p and the sixth pre-gate electrode layer 1406p of the PMOS region (RP). The first gate electrode layer 141 of the NMOS region (RN) and the third metal layer 144_3 of the PMOS region (RP) may be formed by patterning the second pre-gate electrode layer 1402p.

Referring to FIG. 2, the second gate spacer 172 may be formed on at least one side of the third gate stack G3.

A method for manufacturing one or more semiconductor devices according to some aspects of the present disclosure will be described with reference to FIGS. 3 and 19 through 22. For the sake of clear description, redundant description will not be provided.

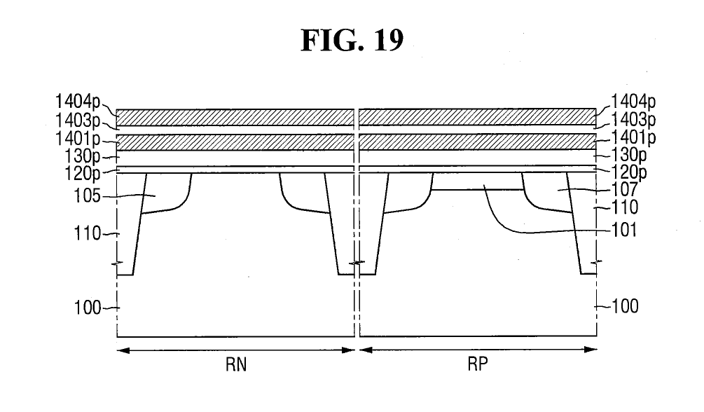

FIGS. 19 through 22 are intermediate step diagrams of a method for manufacturing one or more semiconductor devices according to some aspects of the present disclosure.

Referring to FIG. 19, the pre-interfacial insulating film 120p, the pre-high dielectric constant insulating film 130p, the first pre-gate electrode layer 140p, the third pre-gate electrode layer 1403p, and the fourth pre-gate electrode layer 1404p may be formed to be sequentially laminated on the NMOS region (RN) and the PMOS region (RP) of the substrate 100.

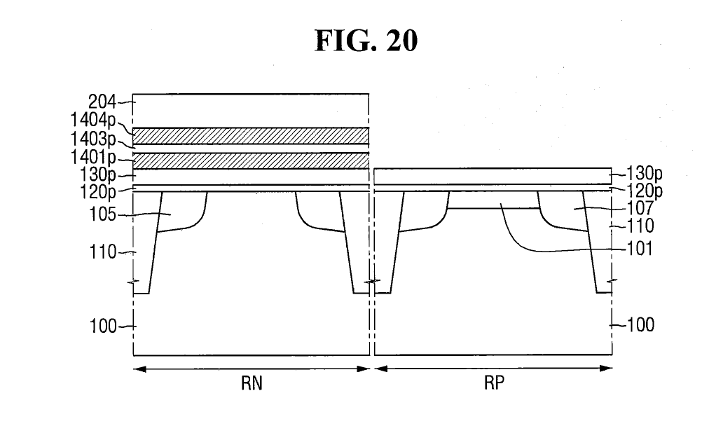

Referring to FIG. 20, the fourth mask 204 may be formed on the fourth pre-gate electrode layer 1404p of the NMOS region (RN) of the substrate 100. The portions of the first pre-gate electrode layer 1401p, the third pre-gate electrode layer 1403p, and the fourth pre-gate electrode layer 1404p of the PMOS region (RP), which are not covered with the fourth mask 204, may be removed, by utilizing the etching selectivity of the pre-high dielectric constant insulating film 130p, the first pre-gate electrode layer 1401p, the third pre-gate electrode layer 1403p, and the fourth pre-gate electrode layer 1404p.

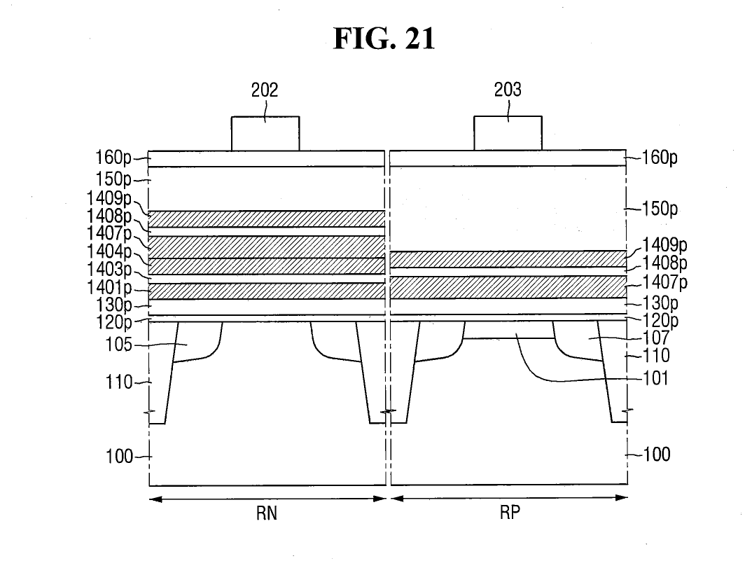

Referring to FIG. 21, after the fourth mask 204 of FIG. 20 is removed, a seventh pre-gate electrode layer 1407p, an eighth pre-gate electrode layer 1408p, a ninth pre-gate electrode layer 1409p, a pre-silicon layer 150p, and a pre-hard mask layer 160p are sequentially formed in the NMOS region (RN) and the PMOS region (RP), and thus, a laminated structure may be formed.

A portion of the seventh pre-gate electrode layer 1407p formed in the NMOS region (RN) may be formed directly on the fourth pre-gate electrode layer 1404p. The fourth pre-gate electrode layer 1404p and the seventh pre-gate electrode layer 1407p may contain, for example, the same material. A portion of the seventh pre-gate electrode layer 1407p formed in the PMOS region (RP) may be formed directly on the pre-high dielectric constant insulating film 130p.

The eighth pre-gate electrode layer 1408p may be formed directly on the seventh pre-gate electrode layer 1407p. The eighth pre-gate electrode layer 1408p may include, for example, the same material as those of the sixth metal layer 143_6 and the ninth gate electrode layer 149 described with reference to FIG. 3.

The ninth pre-gate electrode layer 1409p may be formed directly on the eighth pre-gate electrode layer 1408p. The ninth pre-gate electrode layer 1409p may include, for example, the same material as those of the fifth metal layer 143_5 and the sixth gate electrode layer 146 described with reference to FIG. 3.

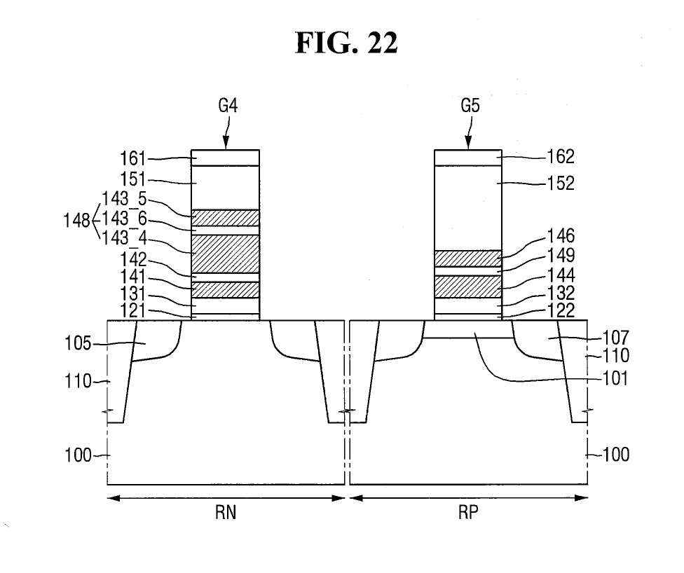

Referring to FIG. 22, a fourth gate stack G4 and a fifth gate stack G5 may be formed. The fourth gate stack G4 may be formed by removing the portion of the laminated structure, which does not overlap the second mask 202 of FIG. 21, until the top surface of the substrate 100 is exposed.

For example, the fourth metal layer 143_4 may be formed by patterning the fourth pre-gate electrode layer 1404p and the seventh pre-gate electrode layer 1407p of the NMOS region (RN). The sixth metal layer 143_6 and the fifth metal layer 143_5 may be formed, for example, by patterning each of the eighth pre-gate electrode layer 1408p and the ninth pre-gate electrode layer 1409p of the NMOS region (RN).

Each of the fourth gate electrode layer 144, the ninth gate electrode layer 149, and the sixth gate electrode layer 146 may be formed, by etching each of the seventh pre-gate electrode layer 1407P, the eighth pre-gate electrode layer 1408p, and the ninth pre-gate electrode layer 1409p of the PMOS region.

Referring to FIG. 3, the first gate spacer 171 may be formed on at least one side of the fourth gate stack G4. Further, the second gate spacer 172 may be formed on at least one side of the fifth gate stack G5.

A method for manufacturing one or more semiconductor devices according to some aspects of the present disclosure will be described with reference to FIGS. 4, 20, 23, and 24. For the sake of clear description, redundant description will not be provided.

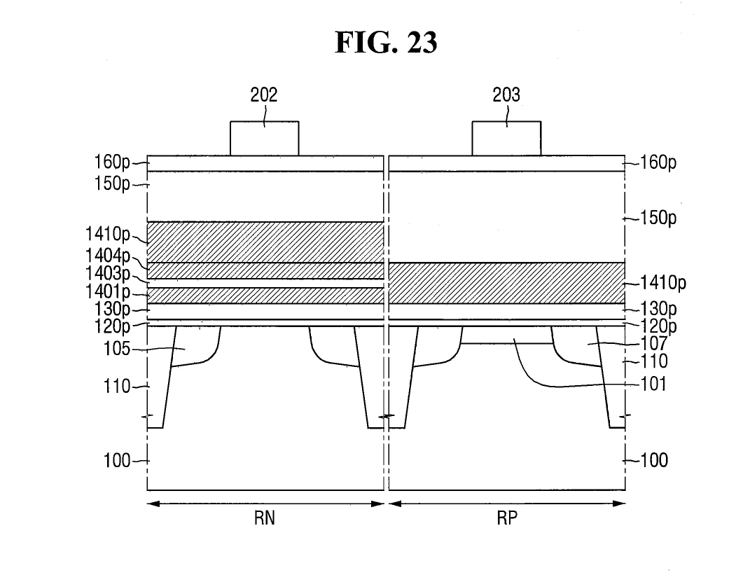

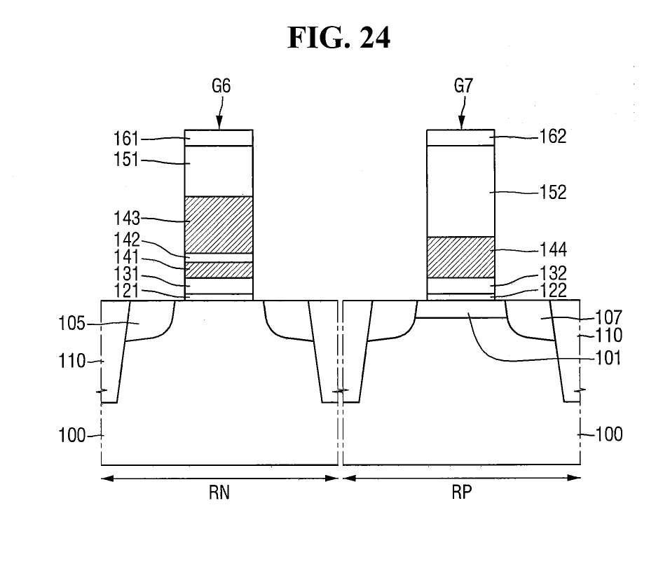

FIGS. 23 and 24 are intermediate step diagrams of a method for manufacturing one or more semiconductor devices according to some aspects of the present disclosure. FIG. 23 is a diagram illustrating the NMOS region (RN) and the PMOS region (RP) after the manufacturing process of the semiconductor device described with reference to FIG. 20 is performed.

Referring to FIG. 23, after the fourth mask 204 of FIG. 20 is removed, a tenth pre-gate electrode layer 1410P, a pre-silicon layer 150p, and a pre-hard mask layer 160p are sequentially formed in the NMOS region (RN) and the PMOS region (RP), and thus, a laminated structure may be formed.

The portion of the tenth pre-gate electrode layer 1410p formed in the NMOS region (RN) may be formed directly on the fourth pre-gate electrode layer 1404p. The portion of the tenth pre-gate electrode layer 1410p formed in the PMOS region (RP) may be formed directly on the pre-high dielectric constant insulating film 130p. The tenth pre-gate electrode layer 1410p may include the same material as that of the fourth pre-gate electrode layer 1404p.

Referring to FIG. 24, a sixth gate stack G6 and a seventh gate stack G7 may be formed. The sixth gate stack G6 may be formed by removing the portion of the laminated structure which does not overlap the third mask 203 of FIG. 23, until the top surface of the substrate 100 is exposed.

The third gate electrode layer 143 may be formed by patterning the fourth pre-gate electrode layer 1404P and the tenth pre-gate electrode layer 1410P of the NMOS region. The fourth gate electrode layer 144 may be formed by patterning the tenth pre-gate electrode layer 1410p of the PMOS region (RP).

Referring to FIG. 4, a first gate spacer 171 may be formed on at least one side of the sixth gate stack G6. Further, a second gate spacer 172 may be formed on at least one side of the seventh gate stack G7.

Although methods for manufacturing semiconductor devices according to some aspects of the present disclosure have been described above, the present disclosure is not limited thereto. For example, semiconductor devices according to some aspects of the present disclosure may be manufactured by methods different from the aforementioned methods for manufacturing semiconductor devices.

While aspects of the present disclosure have been particularly shown and described with reference to exemplary embodiments thereof, it will be understood by those of ordinary skill in the art that various changes in form and details may be made therein without departing from the scope of the present disclosure as defined by the following claims. The embodiments provided herein should be considered in all respects as illustrative and not restrictive, reference being made to the appended claims rather than the foregoing description to indicate the scope of the present application.

1. A semiconductor device comprising:
a substrate including an NMOS region and a PMOS region;
a first transistor in the NMOS region, wherein the first transistor includes a first gate stack and a first source/drain region on at least one side of the first gate stack; and
a second transistor in the PMOS region, wherein the second transistor includes a second gate stack and a second source/drain region on at least one side of the second gate stack,
wherein the first gate stack includes a first high-dielectric constant insulating film, a first gate electrode layer having a first thickness, a second gate electrode layer, a third gate electrode layer, and a first silicon layer which are sequentially laminated,
wherein the second gate stack includes a second high-dielectric constant insulating film, a fourth gate electrode layer having a second thickness greater than the first thickness, a fifth gate electrode layer, a sixth gate electrode layer, and a second silicon layer which are sequentially laminated, and
wherein the second gate electrode layer and the fifth gate electrode layer includes lanthanum.

2. The semiconductor device of claim 1, wherein the first transistor further comprises first gate spacers on at least one side of the first gate stack,
wherein the first, second, and third gate electrode layers and the first silicon layer are between the first gate spacers,
wherein the first high-dielectric constant insulating film does not extend between sidewalls of the first gate spacers and sidewalls of the first, second, and third gate electrode layers,
wherein the second transistor further comprises second gate spacers on at least one side of the second gate stack,
wherein the fourth, fifth, and sixth gate electrode layers and the second silicon layer are between the second gate spacers, and
wherein the second high-dielectric constant insulating film extends only partially between sidewalls of the second gate spacers and sidewalls of the fourth, fifth, and sixth gate electrode layers.

3. The semiconductor device of claim 1, wherein the fourth gate electrode layer includes a first metal layer, a second metal layer, and a third metal layer that are sequentially laminated, and
wherein the second metal layer includes a material different from a material included in the first metal layer and the third metal layer.

4. The semiconductor device of claim 3, wherein each of the first metal layer and the third metal layer includes titanium or tantalum.

5. (canceled)

6. The semiconductor device of claim 3, wherein the second metal layer includes aluminum.

7. (canceled)

8. The semiconductor device of claim 1, wherein the first gate electrode layer is directly on the first high-dielectric constant insulating film, and
the fourth gate electrode layer is directly on the second high-dielectric constant insulating film.

9. The semiconductor device of claim 1, wherein the substrate includes a cell array region and a peripheral region,
wherein the NMOS region and the PMOS region are included in the peripheral region, and
wherein the cell array region includes a buried gate structure.

10. A semiconductor device comprising:
a substrate comprising a cell array region including a buried gate structure, and a peripheral region including a NMOS region and a PMOS region having different conductivity types;
a first transistor in the NMOS region, wherein the first transistor includes a first gate stack, a first source/drain region on at least one side of the first gate stack, and a first channel region below the first gate stack; and
a second transistor in the PMOS region, wherein the first transistor includes a second gate stack, a second source/drain region on at least one side of the second gate stack, and a second channel region below the second gate stack,
wherein the first gate stack includes a first high-dielectric constant insulating film, a first gate electrode layer having a first thickness, a second gate electrode layer, a third gate electrode layer, and a first silicon layer which are sequentially laminated,
wherein the second gate stack includes a second high-dielectric constant insulating film, a fourth gate electrode layer having a second thickness greater than the first thickness, a fifth gate electrode layer, a sixth gate electrode layer, and a second silicon layer which are sequentially laminated,
wherein the first channel region and the second channel region include materials different from each other, and
wherein the second gate electrode layer and the fifth gate electrode layer includes lanthanum.

11. The semiconductor device of claim 10, wherein the first transistor further comprises first gate spacers on at least one side of the first gate stack,
the first, second, and third gate electrode layers and the first silicon layer are between the first gate spacers,
the first high-dielectric constant insulating film does not extend between sidewalls of the first gate spacers and sidewalls of the first, second, and third gate electrode layers,
the second transistor further comprises second gate spacers on at least one side of the second gate stack,
the fourth, fifth, and sixth gate electrode layers and the second silicon layer are between the second gate spacers, and
the second high-dielectric constant insulating film does not extend between sidewalls of the second gate spacers and sidewalls of the fourth, fifth, and sixth gate electrode layers.

12. (canceled)

13. The semiconductor device of claim 10, wherein the fourth gate electrode layer includes a first metal layer, a second metal layer, and a third metal layer that are sequentially laminated, and
the second metal layer includes a material different from a material included in the first metal layer and the third metal layer.

14. The semiconductor device of claim 13, wherein each of the first metal layer and the third metal layer comprises titanium or tantalum.

15. (canceled)

16. The semiconductor device of claim 13, wherein the second metal layer includes aluminum.

17. (canceled)

18. The semiconductor device of claim 10, wherein the buried gate structure includes a buried gate trench, a buried gate insulation film, a buried gate electrode, and a buried gate capping film.

19. The semiconductor device of claim 10, wherein the second channel region includes a material different from the substrate.

20. The semiconductor device of claim 19, wherein the second channel region includes silicon germanium (SiGe).

21. A semiconductor device comprising:
a substrate including an NMOS region and a PMOS region;
a first gate stack on the substrate in the NMOS region;
a first channel region below the first gate stack;
a second gate stack on the substrate in the PMOS region; and
a second channel region which is below the second gate stack and includes a material different from the first channel region,
wherein the first gate stack includes a first high-dielectric constant insulating film, a first gate electrode layer, a second gate electrode layer, a third gate electrode layer, and a first silicon layer which are sequentially laminated,
wherein the second gate stack includes a second high-dielectric constant insulating film, a fourth gate electrode layer, a fifth gate electrode layer, a sixth gate electrode layer, and a second silicon layer which are sequentially laminated,
wherein the second channel region includes germanium,
wherein the first gate electrode layer and the fourth gate electrode layer include the same metal element,
wherein the second gate electrode layer includes lanthanum, and
wherein the fifth gate electrode layer includes lanthanum or aluminum.

22-23. (canceled)

24. The semiconductor device of claim 21, wherein the fourth gate electrode layer includes a first metal layer, a second metal layer, and a third metal layer which are sequentially laminated, and
the second metal layer includes a material different from a material included in the first metal layer and the third metal layer.

25. The semiconductor device of claim 24, wherein the fifth gate electrode layer comprises lanthanum, and the third metal layer comprises aluminum.

26. The semiconductor device of claim 24, wherein the third gate electrode layer includes a fourth metal layer, a fifth metal layer, and a sixth metal layer interposed between the fourth metal layer and the fifth metal layer, and the sixth metal layer includes a material different from a material included in the fourth metal layer and the fifth metal layer.

27. The semiconductor device of claim 26, wherein the sixth metal layer and the fifth gate electrode layer includes aluminum.

28-30. (canceled)
